(19) United States
(12) Patent Application Publication
(10) Pub. No.: US 2008/0151513 A1
(43) Pub. Date: Jun. 26, 2008

(54) High-frequency PCB connections that utilize blocking capacitors between the pins

(76) Inventor: Joseph Parchesky, Dallas, TX (US)

Correspondence Address: LAW OFFICES OF MARK C. PICKERING, P.O. BOX 300, PETALUMA, CA, 94953, US

(21) Appl. No.: 11/643,282

(22) Filed: Dec. 21, 2006

(51) Int. Cl. H05K 1/00; H05K 7/00; H05K 7/10

(52) U.S. Cl. 361/760; 361/767; 439/883

(57) ABSTRACT

The board real estate consumed by a number of blocking capacitors, which are connected to the top surface of a printed circuit board to isolate circuits with different DC voltage levels while permitting a high frequency signal to pass through, and a number of metal-plated holes, which are associated with the blocking capacitors, is substantially reduced by forming the capacitors and metal-plated holes between the pins of a high-frequency connector. Forming the metal-plated holes between the pins of the high-frequency connector reduces the number of metal-plated holes in the signal path. This, in turn, substantially reduces the parasitic capacitive and inductive elements, thereby substantially improving the signal integrity of the PCB design.

### BACKGROUND OF THE INVENTION

1. Field of the Invention

The present invention relates to a printed circuit board (PCB) and, more particularly, to high-frequency PCB connections that utilize blocking capacitors between the pins.

2. Description of the Related Art

A printed circuit board (PCB) is a multi-layered structure that physically supports and electrically interconnects a number of devices, such as integrated circuit chips, discrete devices (capacitors, inductors, and resistors), and connectors. One type of connector that can be used on a PCB is a high-frequency connector with compliant press fit pins.

FIGS. 1A-1C show views that illustrate a prior-art PCB 100. FIG. 1A shows a plan view. FIG. 1B shows a cross-sectional view taken along line 1B-1B of FIG. 1A. FIG. 1C shows a bottom view. As shown in FIGS. 1A-1C, PCB 100 includes an isolation region 110 that has a top surface 110T and a bottom surface 110B. Isolation region 110 is formed from a number of insulation layers 110L.

PCB 100 also includes a number of conductive members 112 that contact isolation region 110. The conductive members 112, which lie in a number of vertically spaced-apart conductive layers 112L between and in contact with the insulation layers 110L, include thin metal (typically copper) traces 112T, metal pads 112P connected to thin metal traces 112T that contact top surface 110T, and sheets of thin metal foil 112E which function as reference planes. The metal traces 112T include metal traces 112T1, 112T2, 112T3, 112T4, and 112T5.

Each metal foil sheet 112E, in turn, occupies an entire layer, except for small holes (anti-pads) to avoid unwanted connections to any metal-plated through-hole. The metal foil sheets 112E provide a means for controlling the transmission line properties of the metal traces 112T. When a metal trace 112T lies close to a metal foil sheet (reference plane) 112E, a signal transmission line is formed. The dielectric properties of the insulating layers, the width and the thickness of the metal trace and its separation from the reference planes determine the impedance of the transmission line. With proper selection of these parameters the impedance of the transmission line formed by metal trace 112T and its associated reference planes can be set to approximately 50Ω. The metal foil sheets (reference planes) 112E can be connected to ground, or to other voltages.

In addition, PCB 100 includes a number of first, second, and third metal-plated holes 114, 116, and 118, respectively, which are illustrated as though holes that extend completely through isolation region 110 from top surface 110T to bottom surface 110B. (Only two first metal-plated holes 114-1 and 114-2, two second metal-plated holes 116-1 and 116-2, and one third metal-plated hole 118 are shown for clarity.) The first, second, and third metal-plated holes 114, 116, and 118 are selectively connected to the metal traces 110T or the metal sheets 110E in the various conductive layers 112L.

Further, the first, second, and third metal-plated holes 114, 116, and 118, which are substantially parallel to each other, have first, second, and third diameters D1, D2, and D3, respectively. The second and third diameters D2 and D3 are substantially equal. The first diameter D1, in turn, is typically larger than the second and third diameters D2 and D3. The first, second, and third metal-plated holes 114, 116, and 118 have first ends 114E1, 116E1, and 118E1 respectively, and second ends 114E2, 116E2, and 118E2, respectively.

PCB 100 additionally includes a high-frequency connector 120 that has a body 120B and a number of conductive compliant press fit pins 120P that extend away from body 120B. (Only two pins 120P1 and 120P2 are shown for clarity.) When connector 120 is attached to PCB 100, the compliant press fit pins 120P are pressed into the first metal-plated holes 114 where the pins 120P mechanically and electrically contact the first metal-plated holes 114. In addition, connector 120 supports a number of signal channels. For example, each channel may use three pins 120P: two pins to support a pair of conductors that carry, for example, a high-frequency differential signal, and one pin to support a ground (reference plane) connection.

PCB 100 also includes a number of blocking capacitors 122 which are connected to the top surface 110T of isolation region 110 to be inserted into the signal paths that carry a high-frequency signal. (Only one blocking capacitor 122 is shown for clarity.) The blocking capacitors 122 isolate circuits with differing DC voltage levels while permitting the high frequency signal to pass through. The plates of each blocking capacitor 122 are electrically connected to a corresponding pair of second metal-plated holes 116, such as second metal-plated holes 116-1 and 116-2, using metal traces, such as metal traces 112T2 and 112T3.

PCB 100 further includes a number of integrated circuit chips 126 (only one integrated circuit chip 126 is shown in FIG. 1 for clarity), and a number of solder balls 128 (only one solder ball 128 is shown in FIG. 1 for clarity). Some of the integrated circuit chips may be in packages, known as ball-grid-arrays (BGA), which contain an array of solder balls 128. The solder balls 128 are electrically connected to the third metal-plated holes 118 using a pad and a metal trace, such as pad 112P and metal trace 112T5, which lie on the top surface 110T of isolation region 110.

For example, as shown in FIG. 1, a signal path extends from connector 120 to integrated circuit chip 126 from pin 120P1 to first metal-plated hole 114-1 to metal trace 112T1 to second metal-plated hole 116-1 to metal trace 112T2 to capacitor 122 to metal trace 112T3 to second metal-plated hole 116-2 to metal trace 112T4 to third metal-plated hole 118 to metal trace 112T5 to pad 112P to solder ball 128.

One problem with PCB 100 is that a large amount of board real estate is required to accommodate the capacitors 122. For example, a capacitor 122, in addition to its own space, requires two second metal-plated holes 116 to electrically contact the top and bottom plates, respectively, of the capacitor 122. The capacitor 122 also requires two second metal-plated holes 116 that electrically connect spaced-apart points on the metal foil sheet 112E (reference plane) that lies directly under capacitor 122 to other reference planes to provide a continuous return path.

Thus, as the number of channels increase, the number of capacitors 122 and second metal-plated holes 116 increase, and occupy an increasingly larger portion of the available PCB real estate, which now can not be used for other circuitry and components. Another problem with PCB 100 is the second metal-plated holes 116 associated with the blocking capacitors 122 have parasitic capacitive and inductive elements that can impair the signal integrity of high-frequency differential signals. This impairment can include signal attenuation and distortion. As a result, there is a need for a reduced-size PCB that can accommodate a large number of channels carrying high-frequency signals, and improve the signal integrity of the high-frequency signals.

### SUMMARY OF THE INVENTION

A printed circuit board is disclosed in accordance with a first embodiment of the present invention. The printed circuit board includes an isolation region that has a top surface and a bottom surface, and a plurality of conductive members that contact the isolation region. The printed circuit board also includes two or more first metal-plated holes that extend into the isolation region from the top surface. The printed circuit board further includes a number of second metal-plated holes that extend into the isolation region from the bottom surface. Each second metal-plated hole lies between and adjacent to the first metal-plated holes.

A printed circuit board is disclosed in accordance with a second embodiment of the present invention. The printed circuit board includes an isolation region that has a top surface and a bottom surface, and two or more metal-plated connector holes that extend into the isolation region from the top surface. The printed circuit board also includes a connector that has a body that contacts the top surface of the isolation region, and two or more pins that extend into the isolation region to contact the metal-plated connector holes. The printed circuit board further includes a number of capacitors that contact the bottom surface of the isolation region.

A printed circuit board is disclosed in accordance with a third embodiment of the present invention. The printed circuit board includes an isolation region that has a top surface and a bottom surface, and two or more metal regions that contact the top surface of the isolation region. The printed circuit board also includes an integrated circuit chip that is connected to the two or more metal regions, and a number of capacitors that contact the bottom surface of the isolation region.

### BRIEF DESCRIPTION OF THE DRAWINGS

FIGS. 1A-1C are views illustrating a prior-art printed circuit board 100. FIG. 1A is a plan view. FIG. 1B is a cross-sectional view taken along line 1B-1B of FIG. 1A. FIG. 1C is a bottom view.

FIGS. 2A-2C are views illustrating an example of a printed circuit board 200 in accordance with the present invention. FIG. 2A is a plan view. FIG. 2B is a cross-sectional view taken along line 2B-2B of FIG. 2A. FIG. 2C is a bottom view.

### DETAILED DESCRIPTION OF THE INVENTION

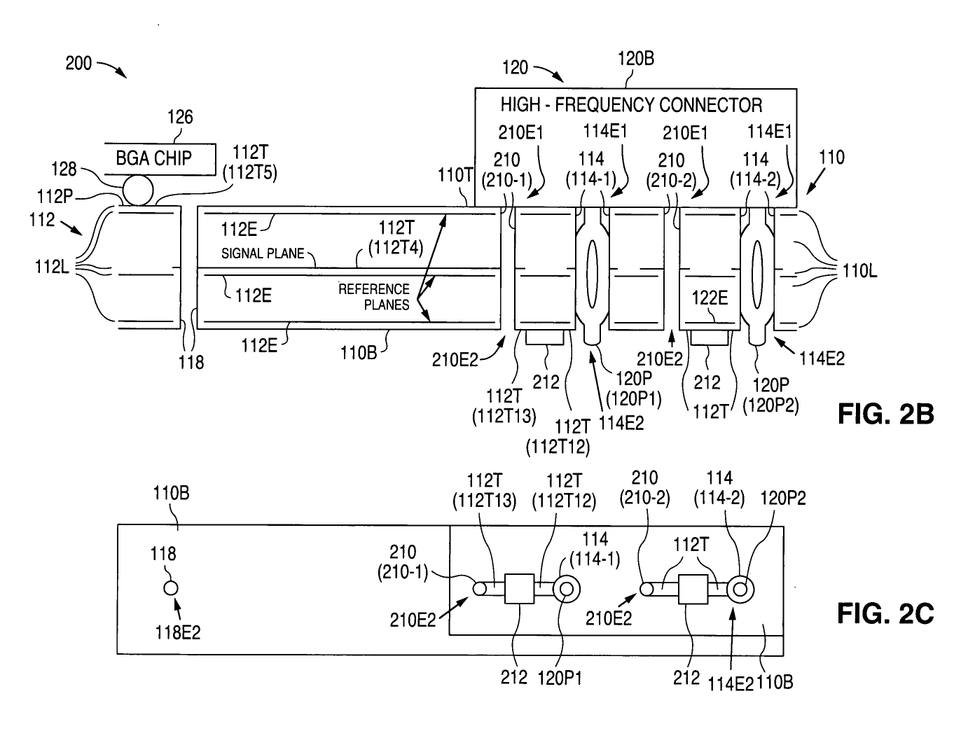

FIGS. 2A-2C show views that illustrate an example of a printed circuit board (PCB) 200 in accordance with the present invention. FIG. 2A shows a plan view. FIG. 2B shows a cross-sectional view taken along line 2B-2B of FIG. 2A. FIG. 2C shows a bottom view. PCB 200 is similar to PCB 100 and, as a result, utilizes the same reference numerals to designate the structures that are common to both boards.

As described in greater detail below, PCB 200 reduces the board real estate that is consumed by the blocking capacitors and second metal-plated holes that are associated with a high-frequency signal connections by relocating the blocking capacitors and metal-plated holes to the PCB area that is between and adjacent to the pins of the high-frequency connector on the bottom side of the PCB.

Further, PCB 200 improves the signal integrity by eliminating a large number of the second metal-plated holes (with their associated parasitic elements) that would normally be associated with the blocking capacitors by making use of the metal-plated holes that are already required for the high-frequency connector.

As shown in FIGS. 2A-2C, one way that PCB 200 differs from PCB 100 is that PCB 200 utilizes a number of fourth metal-plated holes 210 in lieu of the second metal-plated holes 116. (Only two fourth metal-plated holes 210-1 and 210-2 are shown for clarity.) The fourth metal-plated holes 210 are selectively connected to the metal traces 110T or the metal sheets 110E in the various conductive layers 112L.

As shown in the FIGS. 2A-2C example, the fourth metal-plated holes 210 can be implemented as through holes which extend completely through isolation region 110 from top surface 110T to bottom surface 110B. Alternately, the fourth metal-plated holes 210 can be implemented as blind vias, micro vias, or back drilled holes.

Unlike a through hole, a blind via is one that does not go all the way through the board but is still plated to make contact to the various layers as required. A micro via, which is similar except that it is typically drilled with a laser so it can have a diameter smaller than a machine drilled hole, usually only goes in two or three layers from the surface. A back drilled hole is a metal-plated through-hole except the fabricator goes back over the board and selectively drills out the copper plating to a controlled depth.

Further, the first metal-plated holes 114 shown in the FIGS. 2A-2C example, which are shown as through holes, can also be implemented as back drilled holes. In addition, the third metal-plated holes 118 shown in the FIGS. 2A-2C example, which are shown as through holes, can also be implemented as blind vias, micro vias, or back drilled holes.

Other combinations of metal “holes” can additionally be used. For example, a top surface 110T to bottom surface 110B signal path can go from a first blind via to a trace to a buried via to a trace to a second blind via. A buried via is made between two or more internal layers before the final build up and lamination of the PCB and has no connection to any surface layer metal.

Further, the fourth metal-plated holes 210, which are substantially parallel to the first and third metal-plated holes, each have a fourth diameter D4 which is substantially equal to the third diameter D3, and smaller than the first diameter D1. In addition, the fourth metal-plated holes 210 have first ends 210E1 and second ends 210E2.

In accordance with the present invention, the fourth metal-plated holes 210 lie between and adjacent to the first metal-plated holes 114. As a result, as shown in FIG. 2A, the first ends 210E1 of the fourth metal-plated holes 210 lie between and adjacent to the first ends 114E1 of the first metal-plated holes 114. Similarly, as shown in FIG. 2C, the second ends 210E2 of the fourth metal-plated holes 210 lie between and adjacent to the second ends 114E2 of the first metal-plated holes 114.

As shown in FIGS. 2A-2C, PCB 200 also differs from PCB 100 in that PCB 200 includes a number of blocking capacitors 212 that contact the bottom surface 110B of isolation region 110, and lie between and adjacent to the first and fourth metal-plated holes 114 and 210, respectively. PCB 200 also includes a number of metal traces 112T that contact bottom surface 110B of isolation region 110. The metal traces 112T include metal traces 112T12 and 112T13.

Each blocking capacitor 212, in turn, is electrically connected to a first metal-plated hole 114 with a metal trace 112T, such as metal trace 112T12, that contacts the bottom surface 110B of isolation region 110, and a fourth metal-plated hole 210 with a metal trace 112T, such as metal trace 112T13, that contacts the bottom surface 110B of isolation region 110.

As a result, the body 120B of connector 120 lies adjacent to the top surface 110T of isolation region 110, whereas the capacitors 212 contact the bottom surface 110B of isolation region 110, and lie between and adjacent to the second ends 114E2 and 210E2 of the first and fourth metal-plated holes 114 and 210.

Thus, as shown in FIG. 2B, a signal path extends from connector 120 to integrated circuit chip 126 from pin 120P1 to first metal-plated hole 114-1 to metal trace 112T12 to capacitor 212 to metal trace 112T13 to fourth metal-plated hole 210-1 to metal trace 112T4 to third metal-plated hole 118 to metal trace 112T5 to metal pad 112P to solder ball 128.

In addition, a continuous reference (return) path also extends from connector 120 to integrated circuit chip 126 from a pin (like pin 120P1) to a first metal-plated hole (like first metal-plated hole 114-1) to a metal foil sheet 112E that lies just above capacitor 212 to a third metal-plated hole (like third metal-plated hole 118) to metal foil sheet 112E that lies just below a pad (like pad 112P) to a pad (like pad 112P) to a solder ball (like solder ball 128).

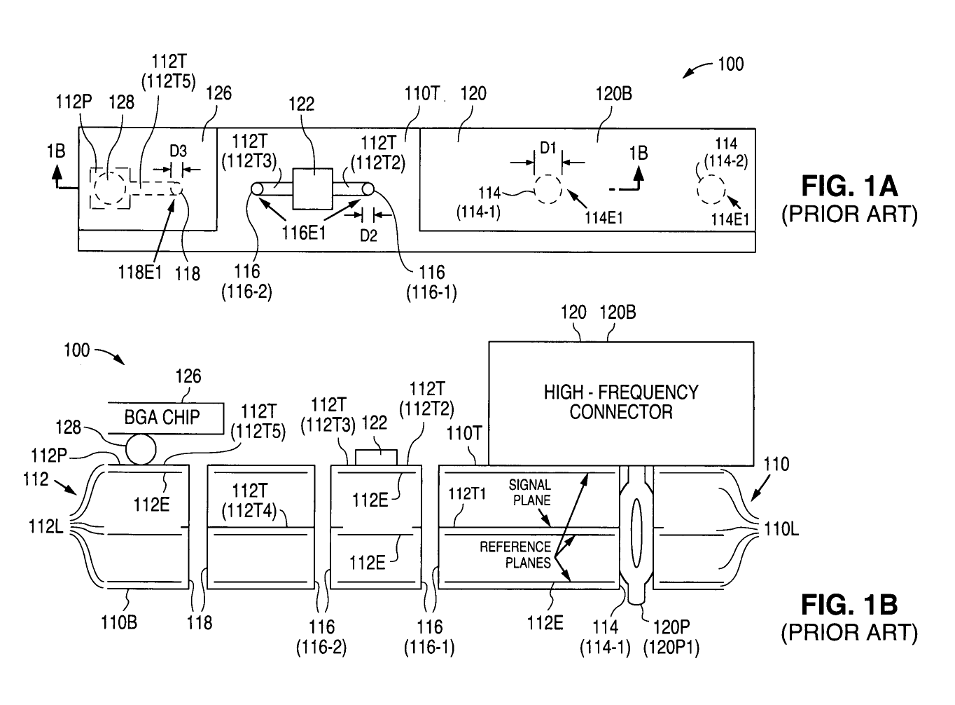

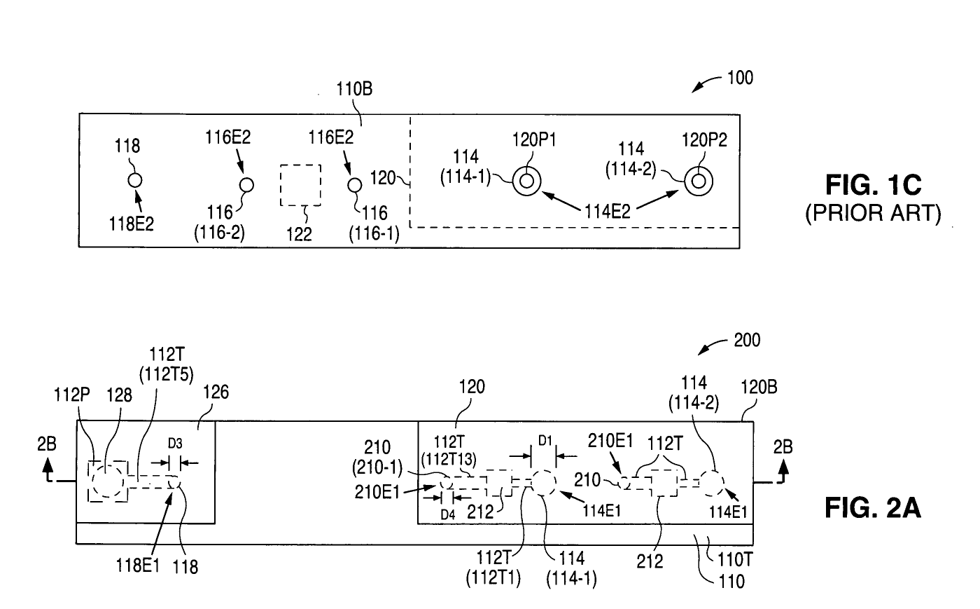

PCB 200 provides a number of advantages over PCB 100. As shown in FIGS. 1A-1C and 2A-2C, PCB 200 significantly reduces the PCB real estate that is required to accommodate the capacitors and the associated second metal-plated holes. By placing the capacitors 212 between and adjacent to the pins 120P of connector 120, the PCB real estate that would normally be required to support the capacitors and metal-plated holes in PCB 100 can be eliminated, thereby permitting the use of a smaller board or, typically, providing more real estate for use by other circuitry and components. The board real estate between and adjacent to the pins 120P in a conventional PCB is not used.

In addition, the present invention reduces the number of metal-plated holes that are required to accommodate the capacitors. Unlike PCB 100, which requires two second metal-plated holes 116 to support a capacitor (one for each plate), the present invention requires only one fourth metal-plated hole 210 to support a capacitor. In the present invention, one plate of a capacitor 212 is electrically connected to a fourth metal-plated hole 210, while the other plate of the capacitor 212 is electrically connected to a first metal-plated hole 114.

Thus, by utilizing a first metal-plated hole 114 to make one of the capacitor plate connections, the number of metal-plated holes required to support a capacitor is reduced. Reducing the number of metal-plated holes in the signal path reduces the parasitic capacitive and inductive elements thereby improving the signal integrity of the PCB design.

Further, the present invention requires fewer metal-plated holes to provide a continuous reference (return) path. As noted above, PCB 100 requires two second metal-plated holes 116 which electrically connect spaced-apart points on the metal foil sheets 112E1 (reference plane that lies directly under the capacitor 122) to other metal foil sheets 112E (other reference planes) to form a continuous reference (return) path.

In the present invention, one point on the metal foil sheet 112E (reference plane) that lies just above the capacitor 212 is electrically connected to a ground pin 120P (by way of a metal trace 112T which is connected to a first metal-plated hole which, in turn, is connected to the pin 120P). Thus, by utilizing a ground pin which lies close to the capacitor 212 to make the reference plate connections, the number of metal-plated holes required to support a continuous reference (return) path is further reduced.

It should be understood that the above descriptions are examples of the present invention, and that various alternatives of the invention described herein may be employed in practicing the invention. Thus, it is intended that the following claims define the scope of the invention and that structures and methods within the scope of these claims and their equivalents be covered thereby.

What is claimed is:

1. A printed circuit board comprising:
an isolation region having a top surface and a bottom surface;
a plurality of conductive members that contact the isolation region;
two or more first metal-plated holes that extend into the isolation region from the top surface; and
a number of second metal-plated holes that extend into the isolation region from the bottom surface, each second metal-plated hole lying between and adjacent to the first metal-plated holes.

2. The printed circuit board of claim 1 and further comprising a connector having a body and two or more pins that extend away from the body, the pins lying within and contacting the first metal-plated holes.

3. The printed circuit board of claim 2 and further comprising a number of capacitors that contact the bottom surface of the isolation region.

4. The printed circuit board of claim 3 wherein each capacitor is electrically connected to a first metal-plated hole with a conductive member, and a fourth metal-plated hole with a conductive member.

5. The printed circuit board of claim 4 wherein the body of the connector lies adjacent to the top surface of the isolation region.

6. The printed circuit board of claim 5 wherein the first metal-plated holes have first ends that contact the top surface of the isolation region, and second ends that contact the bottom surface of the isolation region.

7. The printed circuit board of claim 6 wherein the capacitors lie between the second ends of the first metal-plated holes.

8. The printed circuit board of claim 4 wherein the plurality of conductive members includes metal traces, metal pads, and sheets of metal foil.

9. The printed circuit board of claim 8 wherein the metal traces include layers of metal traces.

10. The printed circuit board of claim 9 and further comprising:
an integrated circuit chip; and
a solder ball connected to the integrated circuit chip and a metal pad that contacts the top surface of the isolation region.

11. The printed circuit board of claim 10 and further comprising two or more third metal-plated holes that extend completely through the isolation region from the top surface to the bottom surface, each first metal-plated hole having a first diameter, each second metal-plated hole having a second diameter that is smaller than the first diameter, each third metal-plated hole having a third diameter substantially equal to the second diameter, each solder ball being electrically connected to a third metal-plated hole using the metal pad and a metal trace.

12. The printed circuit board of claim 11 wherein the first, second, and third metal-plated holes are substantially parallel.

13. The printed circuit board of claim 4 wherein the first and second metal-plated holes are substantially parallel.

14. The printed circuit board of claim 4 wherein the isolation region includes a plurality of layers.

15. The printed circuit board of claim 1 and further comprising a number of capacitors that contact the bottom surface of the isolation region.

16. The printed circuit board of claim 15 wherein each capacitor is electrically connected to a first metal-plated hole with a conductive member, and a fourth metal-plated hole with a conductive member.

17. The printed circuit board of claim 16 wherein the first metal-plated holes have first ends that contact the top surface of the isolation region, and second ends that contact the bottom surface of the isolation region.

18. The printed circuit board of claim 17 wherein the capacitors lie between the second ends of the first metal-plated holes.

19. The printed circuit board of claim 14 wherein the plurality of conductive members include pads that contact the top surface of the isolation region to be electrically connected to an integrated circuit chip.

20. The printed circuit board of claim 19 wherein the capacitors contact the bottom surface of the isolation region.

21. A printed circuit board comprising:
an isolation region having a top surface and a bottom surface;
two or more metal-plated connector holes that extend into the isolation region from the top surface;
a connector having a body that contacts the top surface of the isolation region, and two or more pins that extend into the isolation region to contact the metal-plated connector holes; and
a number of capacitors that contact the bottom surface of the isolation region.

22. The printed circuit board of claim 21 wherein each capacitor is electrically connected to a metal-plated connector hole of the two or more metal-plated connector holes.

23. The printed circuit board of claim 21 wherein two or more capacitors of the number of capacitors lie between the two or more metal-plated connector holes.

24. The printed circuit board of claim 21 and further comprising two or more metal-plated via holes that extend into the isolation region from the bottom surface, the metal-plated via holes being electrically connected to the capacitors.

25. A printed circuit board comprising:
an isolation region having a top surface and a bottom surface;
two or more metal regions that contact the top surface of the isolation region;
an integrated circuit chip connected to the two or more metal regions; and
a number of capacitors that contact the bottom surface of the isolation region.

26. The printed circuit board of claim 25 wherein each capacitor is electrically connected to the integrated circuit chip.

27. The printed circuit board of claim 26 and further comprising:
two or more first metal-plated holes that extend into the isolation region from the top surface; and
a number of second metal-plated holes that extend into the isolation region from the bottom surface, each second metal-plated hole lying between and adjacent to the first metal-plated holes.

28. The printed circuit board of claim 27 wherein two or more capacitors of the number of capacitors lie between the two or more first metal-plated holes and the number of second metal-plated holes.

29. The printed circuit board of claim 28 wherein the first metal-plated holes are electrically connected to the capacitors.
